(19) United States
(12) Patent Application Publication
(10) Pub. No.: US 2001/0035794 A1
(43) Pub. Date: Nov. 1, 2001

(54) Oscillator and communication apparatus

(75) Inventors: Masanori Fujidai, Yokohama-shi (JP); Fumitoshi Sato, Shiga-ken (JP); Toshio Hata, Omihachiman-shi (JP)

Correspondence Address: KEATING & BENNETT LLP, 10400 Eaton Place, Suite 312, Fairfax, VA, 22030, US

(73) Assignee: Murata Manufacturing Co., Ltd., Nagaokakyo-shi (JP)

(21) Appl. No.: 09/844,045

(22) Filed: Apr. 27, 2001

(30) Foreign Application Priority Data
Apr. 27, 2000 (JP) 2000-128346

(51) Int. Cl. H03B 1/04; H03B 5/12; H03B 5/18

(52) U.S. Cl. 331/75; 331/77; 331/117 D; 331/177 V

(57) ABSTRACT

An oscillator includes an oscillating circuit and a resonating circuit connected to the oscillating circuit, and an amplifying circuit for amplifying signals output from the oscillating circuit. The oscillator also includes an added circuit having an isolator, frequency filter, or other suitable elements, disposed between the output portion of the oscillating circuit and the input portion of the amplifying circuit, so as to prevent transmission of unwanted waves, such as the higher harmonic component of the basic wave, and other such undesirable waves. The oscillator, and a communication apparatus including such oscillator, eliminates deterioration of phase noise properties caused by generation of unwanted wave components such as higher harmonics.

### BACKGROUND OF THE INVENTION

1. Field of the Invention

The present invention relates to an oscillator for use in, for example, high-frequency circuits and a communication apparatus including the oscillator.

2. Description of the Related Art

Conventionally, oscillators used for microwave bands and other bands have been configured with Colpitts oscillator circuits or oscillator circuits that are variants thereof.

FIG. 9 illustrates an example of the configuration of a conventional oscillator. Looking at the oscillating circuit 2 shown in FIG. 9, Q1 denotes an oscillating transistor, with a capacitor C1 connected between the base and emitter thereof, the collector is grounded at a high frequency by a capacitor C3, a capacitor C2 is provided between the emitter and ground, and a resonating circuit 1 is provided between the base and ground, thus defining a Colpitts oscillating circuit by configuring an inductive circuit at the portion indicated as being the resonating circuit 1.

Also, with the amplifying circuit 4 in FIG. 9, Q2 denotes a buffer transistor, and oscillating signals from the emitter of the transistor Q1 are transmitted to the base thereof via a capacitor C5.

However, with an oscillator including an oscillating circuit and an amplifying circuit for amplifying the output signals of the oscillating circuit, the oscillating circuit generates not only the oscillating frequency determined by the resonating frequency thereof, but also generates a harmonic such as a secondary harmonic and a third harmonic, and the amplifying circuit amplifies and outputs these higher harmonic components as well. This has been caused deterioration in the phase noise properties of the oscillator.

### SUMMARY OF THE INVENTION

In order to overcome the problems described above, preferred embodiments of the present invention provide an oscillator having minimized deterioration of phase noise properties caused by unwanted waves such as higher harmonics, and a communication apparatus including such a novel oscillator.

According to a preferred embodiment of the present invention, an oscillator includes an oscillating circuit and a resonating circuit connected to the oscillating circuit, and an amplifying circuit for amplifying signals output from the resonating circuit and outputting the amplified signals from an output unit, wherein an added circuit for preventing transmission of unwanted waves is provided between an output portion of the oscillating circuit and an input portion of the amplifying circuit. Thus, unwanted waves such as higher harmonic components and other undesirable waves that are generated at the oscillating circuit are prevented from entering the amplifying circuit, and deterioration in phase noise properties is minimized.

The added circuit may be a filter for cutting out frequency components of the unwanted waves. Also, the frequency to be cut out may be the frequency of the higher order harmonic of the oscillating frequency due to the oscillating circuit. Thus, transmission of unwanted wave components can be effectively prevented.

The added circuit may also be an isolator for carrying signals of a predetermined frequency bandwidth containing the oscillating frequency of the oscillating circuit, from the output portion of the oscillating circuit to the input portion of the amplifying circuit. Thus, transmission of unwanted waves from the oscillating circuit to the amplifying circuit is prevented, and also even in the event that signals are reflected to the oscillating circuit side due to mismatching occurring at the amplifying circuit, the reflected waves are apprehended by the isolator, thereby allowing the oscillating circuit to operate in a stable manner.

Also, according to another preferred embodiment of the present invention, a communication apparatus includes an oscillator according to the preferred embodiment of the present invention described above and a PLL circuit for a local oscillating circuit.

Other features, elements, characteristics and advantages of the present invention will become more apparent from the following detailed description of preferred embodiments of the present invention with reference to the attached drawings.

### BRIEF DESCRIPTION OF THE DRAWINGS

FIG. 1 is a block diagram of an oscillator relating to a first preferred embodiment of the present invention;

FIG. 2 is a circuit diagram of the oscillator of FIG. 1;

FIG. 3 is a diagram illustrating the output power spectrum of the oscillator according to a preferred embodiment of the present invention and a conventional oscillator;

FIG. 4 is a circuit diagram of an oscillator according to a second preferred embodiment of the present invention;

FIG. 5 is a circuit diagram of an oscillator according to a third preferred embodiment of the present invention;

FIGS. 6A and 6B are circuit diagrams of an oscillator according to a fourth preferred embodiment of the present invention;

FIG. 7 is a circuit diagram of an oscillator according to a fifth preferred embodiment of the present invention;

FIG. 8 is a block diagram illustrating the configuration of a communication apparatus according to a sixth preferred embodiment of the present invention; and

FIG. 9 is a diagram illustrating the configuration of a conventional oscillator.

### DETAILED DESCRIPTION OF PREFERRED EMBODIMENTS

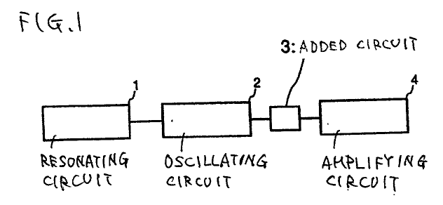

The configuration of an oscillator according to a first preferred embodiment of the present invention will be described with reference to FIGS. 1 through 3.

FIG. 1 is a block diagram of an oscillator. This oscillator preferably includes a resonating circuit 1, an oscillating circuit 2 which oscillates at the resonating frequency of the resonating circuit 1, an amplifying circuit 4 which amplifies the output signals from the oscillating circuit 2, and an added circuit 3 which prevents the unwanted waves in the output signals from the oscillating circuit 2 from being transmitted.

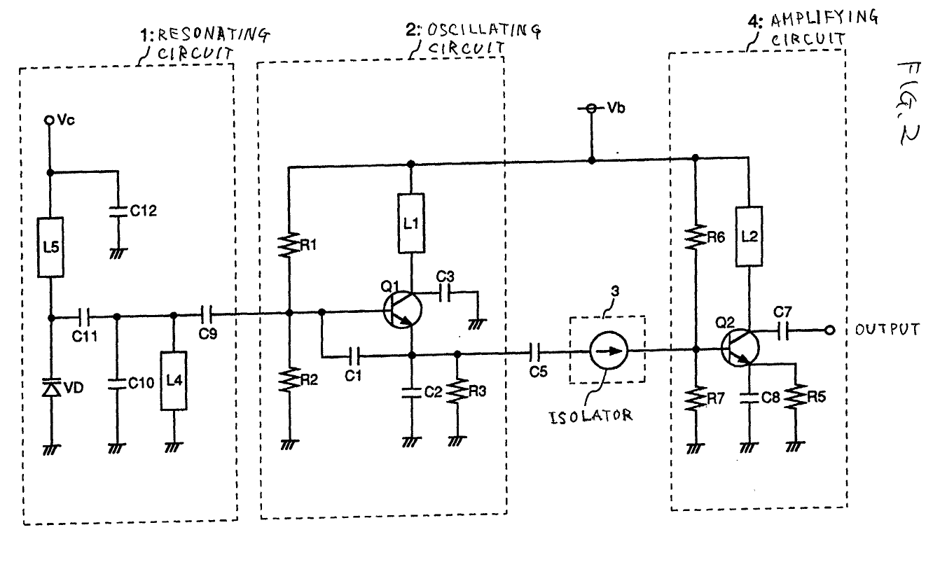

FIG. 2 is a specific circuit diagram of an oscillator. In FIG. 2, Q1 denotes an oscillating transistor, a capacitor C1 is connected between the emitter and base thereof, the collector is connected to the ground at a high frequency via a bypass capacitor C3, a capacitor C2 is connected between the emitter and the ground, and a resonating circuit 1 is connected between the base and the ground, thus defining a Colpitts oscillating circuit.

Also, a strip-line inductor L1 is connected between the collector of Q1 and the power source terminal Vb, a resistor R3 is connected between the emitter and the ground, and further, a voltage dividing circuit including resistors R1 and R2 is connected between the power source terminal Vb and the ground, with the output thereof being connected to the base of Q1.

In the resonating circuit 1, L4 denotes a strip-line inductor, and VD denotes a variable-capacitance diode wherein the electrostatic capacitance changes according to the applied voltage. A filter circuit including a strip-line inductor L5 and a capacitor C12 is provided between the variable-capacitance diode VD and control voltage terminal, such that control voltage is applied to the variable-capacitance diode VD. The reactance of the resonating circuit 1 depends on the inductance of L4, the capacitance of the variable-capacitance diode VD, and the capacitance of the other capacitors C9, C10, and C11. The resonance frequency is determined by the values of these elements and the capacitance of the capacitors C1 and C2 of the oscillating circuit 2, and oscillation is performed at that resonance frequency. Accordingly, the oscillation frequency changes according to the control voltage Vc to be applied.

In the amplifying circuit 4, Q2 denotes a buffer transistor, with a capacitor C8 and resistor R5 connected between the emitter of Q2, and a strip-line inductor L2 connected between the power source terminal Vb and the collector. Also, the output of a voltage dividing circuit including resistors R6 and R7 is transmitted to the base. Further, a capacitor C7 is provided between the collector and output terminal of Q2.

The output of the oscillating circuit 2 is transmitted from the emitter of Q1, and a series circuit of a capacitor C5 and the added circuit 3 is preferably connected between the output portion and the input portion of the amplifying circuit 4 (i.e., the base of Q2). With the present preferred embodiment, the added circuit 3 preferably includes an isolator having low insertion loss properties throughout a predetermined frequency bandwidth with the oscillating frequency as the center frequency thereof.

The isolator described above is preferably a strip-line circulator wherein a strip center conductor is sandwiched between two ferrite plates such that a magnetostatic field is applied in a direction that is substantially perpendicular to the ferrite plates, or a lumped constant circulator wherein the center conductor portion is arranged to be a lumped constant. That is, a terminal resistor for terminating reflecting waves is provided at a predetermined port of these three-port circulators, thus defining an isolator. Alternatively, a two-port isolator is preferably used wherein two center conductors are arranged to intersect each other at a predetermined angle.

The center frequency of the frequency bandwidth in the isolator where the insertion loss in the forward direction decreases preferably is substantially equal to the oscillating frequency of the oscillating circuit 2. By providing such isolator between the oscillating circuit 2 and the amplifying circuit 4, the higher harmonic component which is far away from the above mentioned bandwidth is eliminated, so only the basic wave frequency (the oscillation frequency which should be generated) is amplified by the amplifying circuit 4. Also, reflecting signals due to mismatching of impedance at the connection between the added circuit 3 and the amplifying circuit 4 or mismatching of impedance within the amplifying circuit 4 do not return to the oscillating circuit 2 side, due to the nonreciprocal properties of the isolator. Accordingly, the oscillating circuit 2 operates in a highly reliable and stable manner.

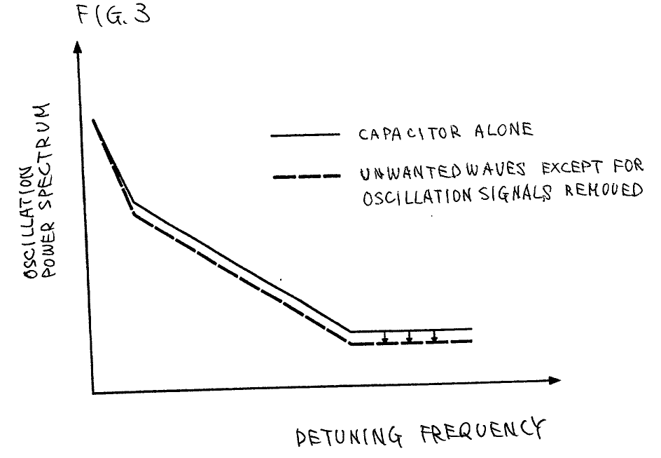

FIG. 3 illustrates the power spectrum of the output signals in a frequency area higher than the basic wave frequency of the above-described oscillator. The solid line in FIG. 3 indicates the properties of an arrangement wherein the added circuit 3 is not included in the arrangement shown in FIG. 2 but rather the output portion of the oscillating circuit 2 and the input portion of the amplifying circuit 4 are connected only with the capacitor C5. The broken line indicates the properties of an arrangement wherein the added circuit 3 is included. As can be understood here, the frequency component that is higher than the oscillating frequency to be output decreases, as the frequency becomes more distant from the basic wave. Thus, phase noise properties improve.

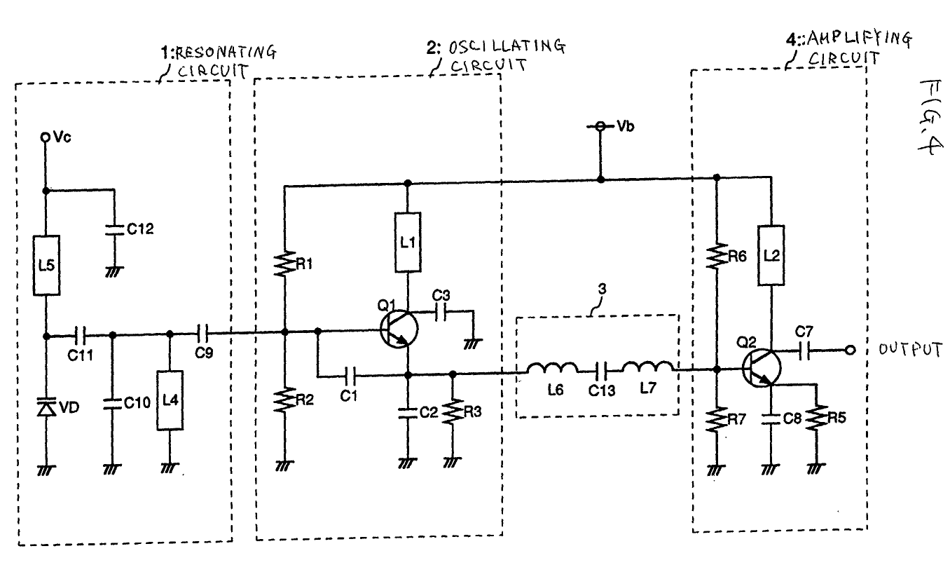

Next, FIG. 4 shows a circuit of an oscillator according to a second preferred embodiment of the present invention. Unlike the preferred embodiment shown in FIG. 2, the added circuit 3 between the output portion of the oscillating circuit 2 and the input portion of the amplifying circuit 4 preferably includes a frequency filter which prevents transmission of unwanted waves. That is, a series circuit including the inductors L6 and L7 and the capacitor C13 constitutes a band-pass filter, in which the center frequency thereof is substantially equal to the oscillation frequency (basic wave frequency) of the oscillating circuit 2. The pass bandwidth of the filter is preferably arranged to eliminate higher harmonic components of the second order or higher. This arrangement in which the added circuit includes a frequency filter also eliminates unwanted wave components, thus allowing phase noise properties to be significantly improved.

FIG. 5 is a circuit diagram of an oscillator according to a third preferred embodiment of the present invention. With this preferred embodiment as well, the added circuit 3 preferably includes a frequency filter, but a low-pass filter including the capacitors C5, C14, and the inductor L8 is preferably used. The cutout frequency for this filter is preferably substantially equal to either the basic wave frequency that is the oscillating frequency of the oscillating circuit 2, or a predetermined frequency that is between the basic wave frequency and the second harmonic frequency. Thus, higher harmonic components are eliminated and phase noise properties are greatly improved.

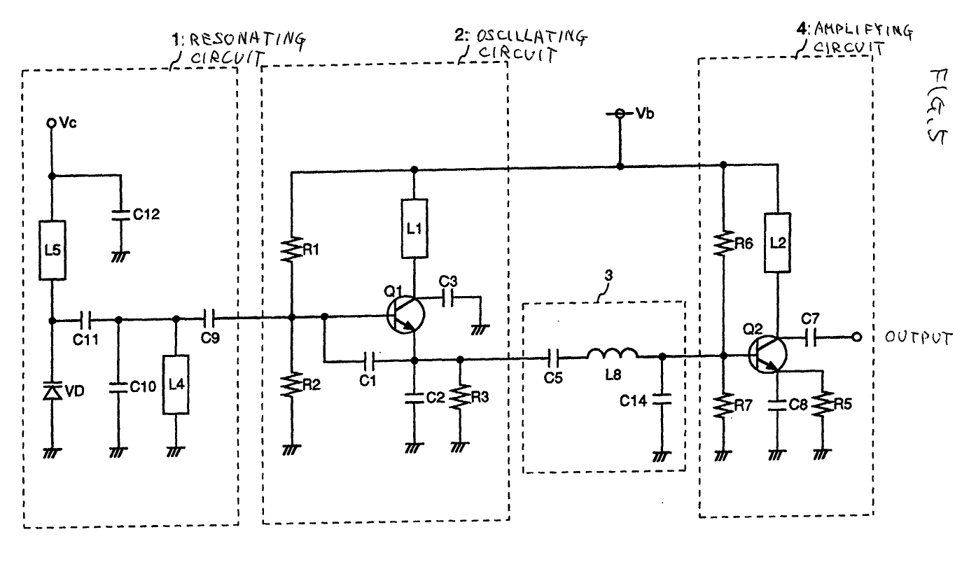

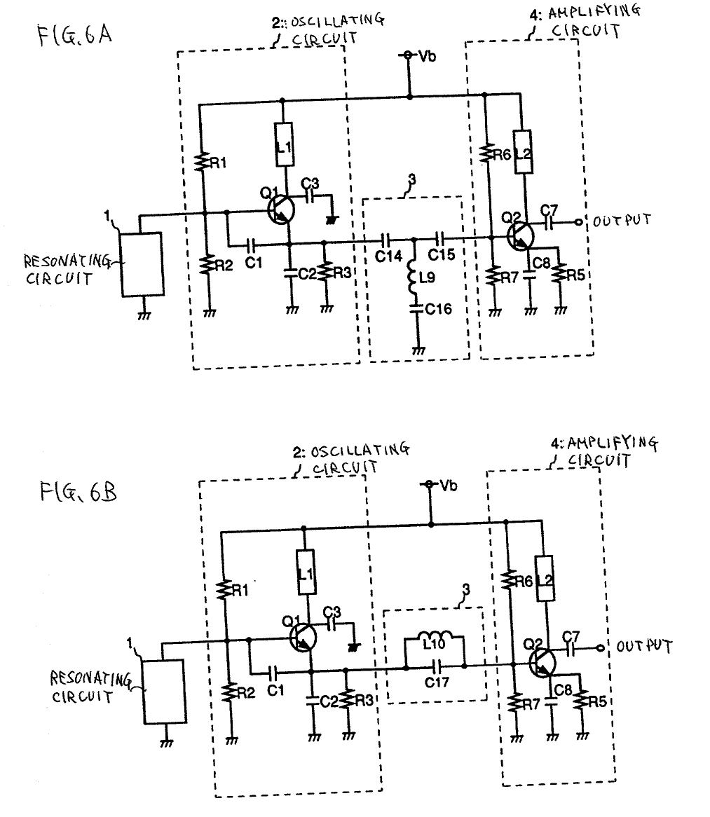

FIGS. 6A and 6B are circuit diagrams of oscillators according to a fourth preferred embodiment of the present invention. With the preferred embodiment shown in FIG. 6A, a band elimination filter including the capacitors C14, C15, and C16, and the inductor L9, functions as the added circuit 3. Also, a band elimination filter of another configuration is preferably included in the preferred embodiment shown in FIG. 6B. In this preferred embodiment, a parallel circuit including an inductor L10 and capacitor C17 is connected between the output portion of the oscillating circuit 2 and the input portion of the amplifying circuit 4.

With either arrangement shown in FIGS. 6A and 6B, the center frequency of the band elimination filter is preferably substantially equal to the frequency of the higher harmonic (e.g., third harmonic) which should be suppressed the most. Thus, transmission of unwanted waves are efficiently eliminated.

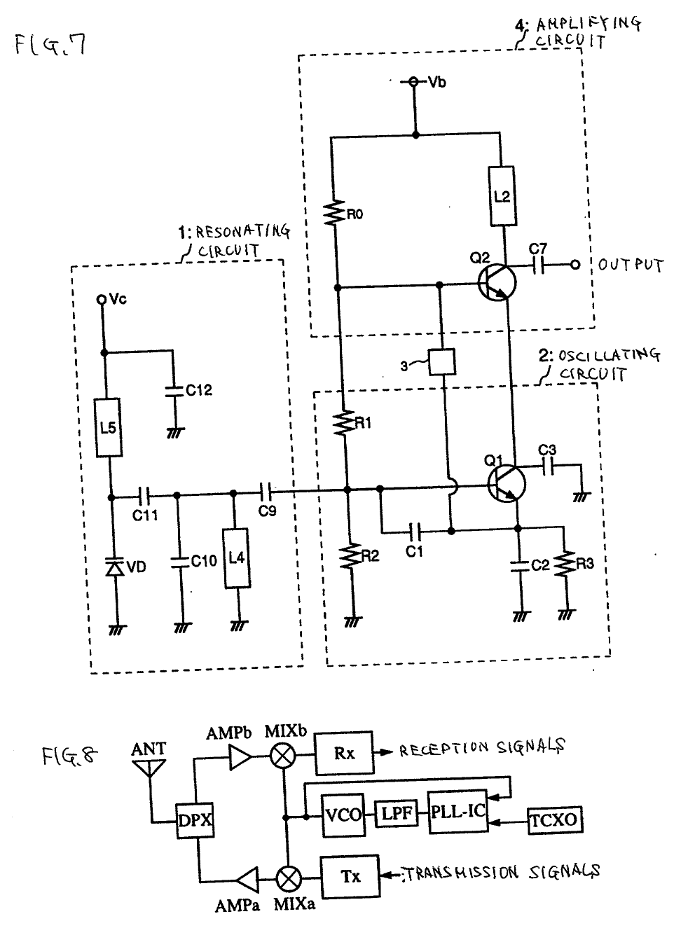

Next, FIG. 7 illustrates an oscillator according to a fifth preferred embodiment of the present invention. This oscillator has the oscillating circuit 2 and the amplifying circuit 4 arranged in a cascade connection. The collector of the oscillating transistor Q1 is connected to the emitter of the buffer transistor Q2, and the inductor L2 is connected between the collector of Q2 and the power source terminal Vb. Also, a voltage dividing circuit including resistors R0, R1, and R2 is connected between the power source terminal Vb and the ground, and the two outputs thereof are connected to the bases of Q1 and Q2, respectively. Further, an added circuit 3 is connected between the emitter of Q1 and the base of Q2.

With such a circuit configuration as well, the added circuit 3 functions as a circuit to prevent transmission of unwanted waves, thereby similarly improving phase noise properties.

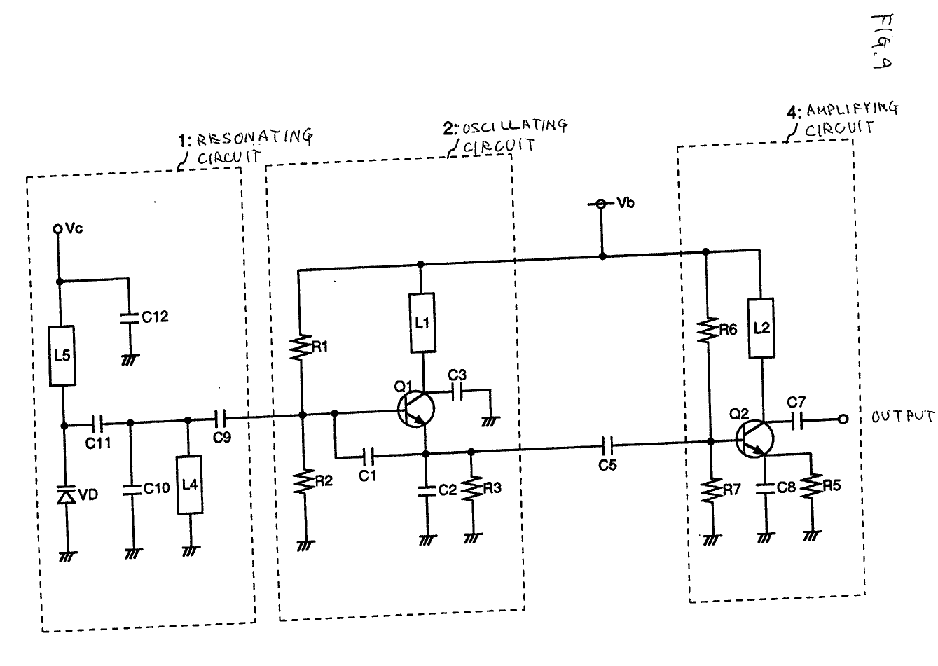

Next, FIG. 8 is a block diagram illustrating an example of a communication apparatus according to a sixth preferred embodiment of the present invention. In FIG. 8, VCO denotes a voltage control oscillator. PLL-IC denotes a PLL control circuit, which receives the output signals of the VCO, performs phase comparison with the oscillating signals of a temperature compensation crystal oscillator TCXO, and outputs control signals having a predetermined frequency and phase. The VCO receives the control voltage with a control terminal via a low-pass filter LPF, and oscillates at a frequency corresponding to the control voltage. These oscillation output signals are supplied to the mixer circuits MIXa and MIXb respectively, as local oscillation signals. The mixer circuit MIXa mixes the intermediate frequency signals output from the transmitting circuit Tx and the local oscillation signals, and performs frequency conversion to the transmission frequency signals. These signals are subjected to power amplification at the amplifying circuit AMPa, and are radiated from the antenna ANT via the duplexer DPX. Reception signals from the antenna ANT are amplified at the amplifying circuit AMPb via the duplexer DPX. The mixer circuit MIXb mixes the output signals of the amplifying circuit AMPb and the local oscillation signals, and converts the signals into intermediate frequency signals. The receiving circuit Rx obtains reception signals by subjecting these signals to signal processing.

The oscillators described in the first through fifth preferred embodiments are preferably usable as the VCO in the above communication apparatus.

Thus, using oscillators with excellent phase noise properties provides superior communication capabilities with no spurious interference.

According to preferred embodiments of the present invention, unwanted waves such as higher harmonic components and other waves generated at the oscillating circuit are not input to the amplifying circuit, thereby minimizing deterioration in phase noise properties.

Also, since the filter properties prevent transmission of higher harmonic frequencies of oscillation frequency due to the oscillating circuit, unwanted wave components are efficiently prevented.

Also, by using an isolator that sends predetermined frequency bandwidth signals containing the oscillation frequency of the oscillating circuit to the amplifier, transmission of unwanted waves from the oscillating circuit to the amplifying circuit is prevented. Also, the oscillating circuit can operate in a stable manner even if signals are reflected toward the oscillating circuit side because of mismatching occurring at the amplifying circuit.

Also, with preferred embodiments of the present invention, a PLL circuit for a local oscillation circuit is provided by using an oscillator configured as described above, and a communication apparatus having excellent communication capabilities without spurious interference can be obtained.

While preferred embodiments have been described above, it is to be understood that modifications and changes will be apparent to those skilled in the art without departing from the spirit of the invention. The scope of the present invention is therefore to be determined solely by the appended claims.

What is claimed is:

1. An oscillator comprising:
an oscillating circuit;
a resonating circuit connected to the oscillating circuit;
an amplifying circuit arranged to amplify signals output from said oscillating circuit; and
an added circuit arranged to prevent transmission of unwanted waves and disposed between an output portion of said oscillating circuit and an input portion of said amplifying circuit.

2. An oscillator according to claim 1, wherein said added circuit includes a frequency filter arranged to cut out frequency components of said unwanted waves.

3. An oscillator according to claim 2, wherein said frequency to be cut out is the frequency of a higher order harmonic of the oscillating frequency of signals generated by said oscillating circuit.

4. An oscillator according to claim 1, wherein said added circuit includes an isolator arranged to carry signals of a predetermined frequency bandwidth containing the oscillating frequency of said oscillating circuit, from the output portion of said oscillating circuit to the input portion of said amplifying circuit.

5. An oscillator according to claim 4, wherein said isolator includes a strip-line circulator having a strip center conductor sandwiched between two ferrite plates such that a magnetostatic field is applied in a direction that is substantially perpendicular to the ferrite plates.

6. An oscillator according to claim 4, wherein said isolator includes a lumped constant circulator having a center conductor portion arranged to be a lumped constant.

7. An oscillator according to claim 4, wherein said isolator includes a terminal resistor arranged to terminate reflecting waves.

8. An oscillator according to claim 4, wherein said isolator includes a two-port isolator having two center conductors arranged to intersect each other at a predetermined angle.

9. An oscillator according to claim 4, wherein said isolator has a center frequency of the frequency bandwidth that is substantially equal to the oscillating frequency of the oscillating circuit.

10. An oscillator according to claim 1, wherein said oscillating circuit is a Colpitts oscillating circuit.

11. An oscillator according to claim 10, wherein said resonating circuit includes a strip-line inductor, and a variable-capacitance diode arranged such that the electrostatic capacitance changes according to the applied voltage.

12. An oscillator according to claim 1, wherein said amplifying circuit includes a buffer transistor, a capacitor and a resistor, and a strip-line inductor.

13. An oscillator according to claim 2, wherein said frequency filter includes a low-pass filter having capacitors and at least one inductor.

14. An oscillator according to claim 2, wherein said frequency to be cut out is substantially equal to one of the basic wave frequency that is the oscillating frequency of the oscillating circuit and a predetermined frequency that is between the basic wave frequency and the second harmonic frequency.

15. An oscillator according to claim 2, wherein said frequency filter includes a band elimination filter having capacitors and at least one inductor.

16. An oscillator according to claim 1, wherein the oscillating circuit and the amplifying circuit are arranged in a cascade connection.

17. A communication apparatus, comprising an oscillator according to claim 1.

18. A communication apparatus according to claim 17, wherein said added circuit includes a frequency filter arranged to cut out frequency components of said unwanted waves.

19. A communication apparatus according to claim 18, wherein said frequency to be cut out is the frequency of a higher order harmonic of the oscillating frequency of signals generated by said oscillating circuit.

20. A communication apparatus according to claim 17, wherein said added circuit includes an isolator arranged to carry signals of a predetermined frequency bandwidth containing the oscillating frequency of said oscillating circuit, from the output portion of said oscillating circuit to the input portion of said amplifying circuit.
